(19) United States
(12) Patent Application Publication
(10) Pub. No.: US 2026/0047376 A1
(43) Pub. Date: Feb. 12, 2026

(54) SUBSTRATE TRANSFER APPARATUS AND SUBSTRATE PROCESSING SYSTEM INCLUDING THE SAME

(71) Applicant: SEMES CO., LTD., Cheonan-si (KR)

(72) Inventors: Joon Hee LEE, Suwon-si (KR); Jae Seung YU, Seoul (KR); Min Young KIM, Hwaseong-si (KR); Min Woo KIM, Seoul (KR); Byeong Kwan KIM, Hwaseong-si (KR); Ju Yeon CHO, Suwon-si (KR)

(73) Assignee: SEMES CO., LTD., Cheonan-si (KR)

(21) Appl. No.: 19/285,365

(22) Filed: Jul. 30, 2025

(30) Foreign Application Priority Data
Aug. 6, 2024 (KR) 10-2024-0104803

(51) Int. Cl. H01L 21/67; B25J 11/00; B25J 19/00

(52) U.S. Cl. CPC H01L 21/67017; B25J 11/0095; B25J 19/0079

(57) ABSTRACT

Disclosed is a substrate transfer apparatus disposed in a transfer chamber, the substrate transfer apparatus including: a robot main body having hands supporting a substrate; and a driving unit for moving the robot main body in a straight direction, wherein the driving unit includes: a driving case having an inner space; an actuator provided within the driving case, and connected to the robot main body; a cable veyor provided on one side of the actuator to guide the cable connected to the robot main body; an exhaust fan for exhausting atmosphere of the inner space; and an intake manifold for receiving suction force of the exhaust fan through a first intake path connected to the exhaust fan to intake a space where the cable veyor is located.

### CROSS-REFERENCE TO RELATED APPLICATION

This application claims priority to and the benefit of Korean Patent Application No. 10-2024-0104803 filed in the Korean Intellectual Property Office on Aug. 6, 2024, the entire contents of which are incorporated herein by reference.

### TECHNICAL FIELD

The present invention relates to a substrate transfer apparatus for transferring a substrate.

### BACKGROUND ART

In the semiconductor manufacturing process, the photolithography process is a process of forming a desired resist pattern by applying a resist solution to a substrate and exposing and developing the substrate by using a photomask. This photolithography process includes a resist solution application process, an exposure and development process. The substrate transfer apparatus transfers a substrate to a processing unit (or process chamber) that processes each process.

Such a substrate transfer apparatus creates a gap between a seal belt and a cover due to the weakening of the seal belt tension during continuous use of a driving unit, resulting in the problem of particles generated in a cable tray and an LM guide inside the driving unit flowing back to the substrate transfer section.

Of course, the driving unit of the substrate transfer apparatus is equipped with an exhaust fan, but the entire driving unit cannot be exhausted only by the exhaust fan, and even if the capacity of the exhaust fan is increased, it is impossible to discharge all friction particles of the driving unit when the internal volume airflow is discharged.

### SUMMARY OF THE INVENTION

The present invention has been made in an effort to provide a substrate transfer apparatus and a substrate processing apparatus capable of preventing particles from flowing back to a substrate transfer section.

The present invention has also been made in an effort to provide a substrate transfer apparatus and a substrate processing apparatus capable of directly absorbing particles generated around a cable veyor and from a linear motion guide to prevent particles from being accumulated in a corresponding area.

The objectives of the present disclosure are not limited thereto and other objectives not stated herein may be clearly understood by those skilled in the art from the following description.

An exemplary embodiment of the present invention, a substrate transfer apparatus disposed in a transfer chamber, the substrate transfer apparatus comprising: a robot main body having hands supporting a substrate; and a driving unit for moving the robot main body in a straight direction, wherein the driving unit may include: a driving case having an inner space; an actuator provided within the driving case, and connected to the robot main body; a cable veyor provided on one side of the actuator to guide the cable connected to the robot main body; an exhaust fan for exhausting atmosphere of the inner space; and an intake manifold for receiving suction force of the exhaust fan through a first intake path connected to the exhaust fan to intake a space where the cable veyor is located.

According to the exemplary embodiment of the present invention, the apparatus may further include a second intake path connected with the exhaust pan and the actuator to exhaust internal atmosphere of the actuator.

According to the exemplary embodiment of the present invention, the actuator includes a linear motion guide having a shielding function, and the linear motion guide includes: a case having an opening; a slider mounted to be movable along the opening with respect to the case; and a seal plate for blocking the opening of the case and allowing the slider to move at the same time, and the case may include an intake port connected to the second intake path.

According to the exemplary embodiment of the present invention, the apparatus may further include a regulator that is provided on the second intake path and regulates suction force provided to an inside of the actuator so that the inside of the actuator maintains a constant pressure.

According to the exemplary embodiment of the present invention, the intake manifold is provided side by side along a longitudinal direction of the cable veyor and may be intake holes on one side facing the cable veyor.

According to the exemplary embodiment of the present invention, the apparatus may further include a pressure measuring device for measuring an internal pressure of the driving case; and a controller for controlling a rotational speed of the exhaust fan according to a measured value of the pressure measuring device.

According to the exemplary embodiment of the present invention, the apparatus may further include an exhaust duct through which airflow is exhausted through the exhaust fan; a particle measuring device for detecting particles from airflow exhausted through the exhaust duct; and a controller for controlling a rotational speed of the exhaust fan according to a measured value of the particle measuring device.

According to the exemplary embodiment of the present invention, the exhaust fan integrates and exhausts main exhaust airflow inside the driving case, first sub exhaust airflow of the first intake path connected to the intake manifold, and second sub may exhaust airflow of the second intake path connected to the actuator.

According to the exemplary embodiment of the present invention, the actuator may be horizontally installed inside the driving case to move the robot main body in a horizontal direction.

According to the exemplary embodiment of the present invention, the actuator may be vertically installed inside the driving case to move the robot main body in a vertical direction.

An exemplary embodiment of the present invention, a substrate processing apparatus comprising: a transfer chamber; and a transfer apparatus disposed within the transfer chamber to transfer a substrate, wherein the transfer apparatus includes: a robot main body having hands supporting a substrate; a vertical driving unit for moving the robot main body in a vertical direction; and a horizontal driving unit provided at a bottom end of the transfer chamber to move the vertical driving unit in a horizontal direction, and the horizontal driving unit includes: a horizontal case having an inner space; a first actuator provided horizontally within the horizontal case and connected to the vertical driving unit; a first cable veyor that is provided on one side of the first actuator to guide the cable connected to the vertical driving unit; a first exhaust fan for exhausting atmosphere of the inner space; and a first intake manifold for receiving suction force of the first exhaust fan through a first intake path connected to the first exhaust fan to intake a space where the first cable veyor may be located.

According to the exemplary embodiment of the present invention, the horizontal driving unit further may include a second intake path connecting the first exhaust fan and the first actuator to exhaust internal atmosphere of the first actuator.

According to the exemplary embodiment of the present invention, the first actuator includes a linear motion guide having a shielding function, and the linear motion guide may include, a case having an opening and an intake port connected to the second intake path; a slider mounted to be movable along the opening with respect to the case; and a seal plate capable of blocking the opening of the case and allowing the slider to move at the same time.

According to the exemplary embodiment of the present invention, the apparatus may further include a regulator that is provided on the second intake path and regulates suction force provided to an inside of the first actuator so that the inside of the first actuator maintains a constant pressure.

According to the exemplary embodiment of the present invention, the intake manifold is provided side by side along a longitudinal direction of the first cable veyor and may has intake holes on one side facing the first cable veyor.

According to the exemplary embodiment of the present invention, the apparatus may further include a controller for controlling a rotational speed of the first exhaust fan, wherein the controller may controls the first exhaust fan according to a change in an internal pressure of the horizontal case or the amount of particles contained in the airflow exhausted through the first exhaust fan.

According to the exemplary embodiment of the present invention, the first exhaust fan integrates and exhausts main exhaust airflow inside the vertical case, first sub exhaust airflow of the first intake path connected to the intake manifold, and second sub may exhaust airflow of the second intake path connected to the first actuator.

According to the exemplary embodiment of the present invention, the vertical driving unit may include, a vertical case having an inner space; a second actuator provided vertically within the vertical case and connected to the robot main body; a second cable veyor that is provided on one side of the second actuator to guide a cable connected to the robot main body; a second exhaust fan for exhausting atmosphere of the inner space; and a second intake manifold for receiving suction force of the second exhaust fan through a third intake path connected to the second exhaust fan to intake a space where the second cable veyor is located; a fourth intake path connecting the second exhaust fan and the second actuator to exhaust internal atmosphere of the second actuator; and a regulator that is provided on the fourth intake path and regulates suction force provided to the inside of the second actuator so that the inside of the second actuator maintains a constant pressure.

An exemplary embodiment of the present invention, a substrate transfer apparatus disposed in a transfer chamber, the substrate transfer apparatus comprising: a robot main body having hands supporting a substrate; and a driving unit for moving the robot main body in a straight direction, wherein the driving unit includes: a driving case having an inner space; a linear motion guide provided in the driving case, connected to the robot body, and having a shielding function; a cable veyor provided on one side of the linear motion guide to guide a cable connected to the robot main body; an exhaust fan for exhausting atmosphere of the inner space; and an intake manifold for receiving suction force of the exhaust fan through a first intake path connected to the exhaust fan to intake a space where the cable veyor is located; a second intake path connecting the exhaust fan to the linear motion guide to exhaust internal atmosphere of the linear motion guide; and a regulator that is provided on the second intake path and regulates suction force provided to an inside of the linear motion guide so that the inside of the linear motion guide maintains a certain pressure, and the linear motion guide includes: a case having an opening and an intake port connected to the second intake path; a slider mounted to be movable along the opening with respect to the case; and a seal plate for blocking the opening of the case and allowing the slider to move at the same time, and the intake manifold is provided side by side along a longitudinal direction of the cable veyor and has intake holes on one side facing the cable veyor, and the exhaust fan integrates and exhausts main exhaust airflow inside the driving case, first sub exhaust airflow of the first intake path connected to the intake manifold, and second sub exhaust airflow of the second intake path connected to the linear motion guide.

According to the exemplary embodiment of the present invention, the apparatus may further include a controller for controlling a rotational speed of the exhaust fan, wherein the controller may controls the exhaust fan according to a change in an internal pressure of the driving case or the amount of particles contained in the airflow exhausted through the exhaust fan.

According to the exemplary embodiment of the present invention, it is possible to prevent particles from flowing back to a substrate transfer section.

According to the exemplary embodiment of the present invention, it is possible to prevent particles from being accumulated in a corresponding area by directly absorbing particles generated around a cable veyor and from a linear motion guide.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a perspective view schematically illustrating a substrate processing apparatus according to an exemplary embodiment of the present invention.

FIG. 2 is a cross-sectional view of the substrate processing apparatus illustrating a coating block or a developing block of FIG. 1.

FIG. 3 is a plan view of the substrate processing apparatus of FIG. 1.

FIG. 4 is a diagram illustrating an example of a hand of a transfer robot.

FIG. 5 is a plan view schematically illustrating one example of a heat processing chamber of FIG. 3.

FIG. 6 is a front view of the heat processing chamber of FIG. 5.

FIG. 7 is a cross-sectional view illustrating an exemplary embodiment of a liquid processing chamber for liquid-processing a substrate by supplying a processing liquid to a rotating substrate.

FIG. 8 is a plan view of the liquid processing chamber of FIG. 7.

FIG. 9 is a perspective view illustrating an example of the transfer robot of FIG. 3.

FIG. 10 is a diagram illustrating a transfer chamber in which the transfer robot of FIG. 9 is installed.

FIG. 11 is a plan view of the transfer robot.

FIG. 12 is a diagram for describing a horizontal driving unit.

FIG. 13 is a diagram illustrating integrated exhaust of an exhaust fan.

FIG. 14 is a diagram for describing a vertical driving unit.

### DETAILED DESCRIPTION

The advantages and features of the present invention, and methods of achieving them will be clear by referring to the exemplary embodiments that will be describe hereafter in detail with reference to the accompanying drawings. However, the present invention is not limited to the exemplary embodiments described hereafter and may be implemented in various ways, and the exemplary embodiments are provided to complete the description of the present invention and let those skilled in the art completely know the scope of the present invention and the present invention is defined by claims.

If not defined, all of terms (including technical or scientific terms) used herein have the same meanings as those that are generally received by general technologies in the field. Terms defined by general dictionaries may be construed as having the same meanings as those in the related technologies and the specification, and even if not explicitly defined here, they will not be conceptualized or excessively construed. The terms used herein are provided to describe embodiments without limiting the present invention.

In the specification, a singular form includes a plural form unless specifically stated in the sentences. The term “comprise” used in the specification and/or its various forms, such as “comprising”, “comprised”, etc. do not exclude the presence or addition of one or more other compositions, components, elements, steps, operations, and/or devices. Further, terms “provide, “have”, etc. also should be construed in the same way.

The system in the present exemplary embodiment is described as being used to perform photolithography processes on substrates, such as semiconductor wafers or flat panel displays, but this is for convenience of description, and the present invention may also be used in other devices including robots that transfer substrates to process substrates.

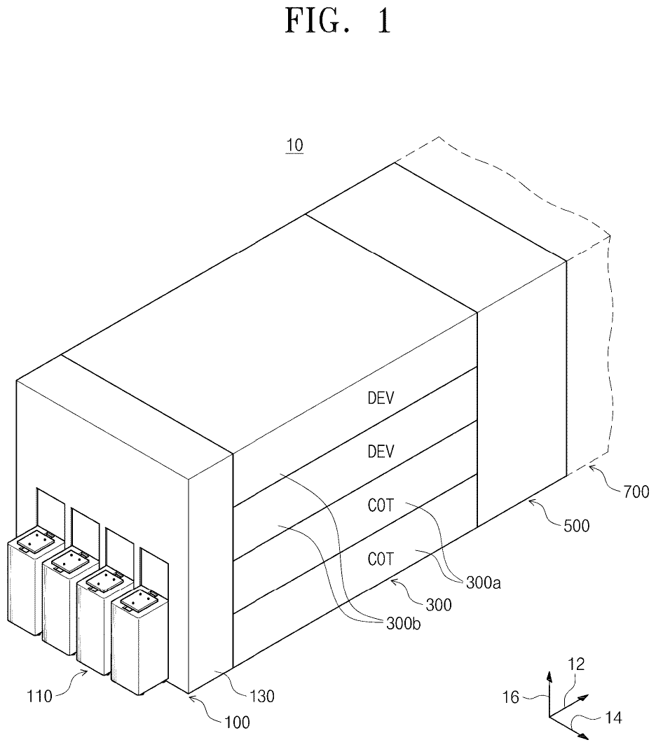

Hereinafter, an exemplary embodiment of the present invention will be described with reference to FIGS. 1 to 14.

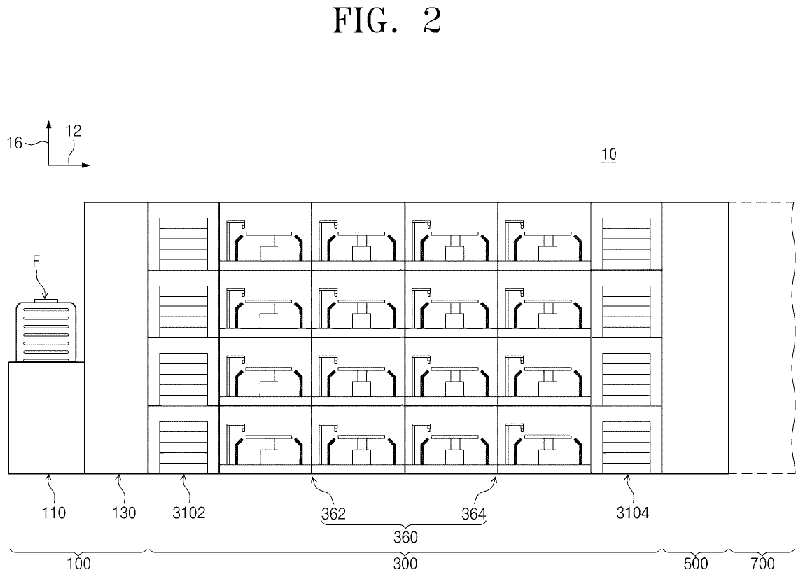

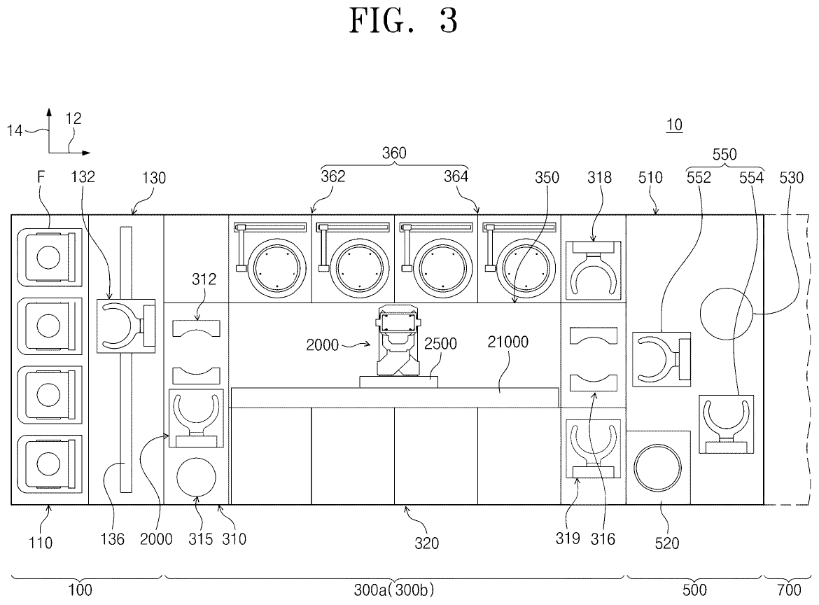

FIG. 1 is a perspective view schematically illustrating a substrate processing apparatus according to an exemplary embodiment of the present invention, FIG. 2 is a cross-sectional view of the substrate processing apparatus illustrating a coating block or a developing block of FIG. 1, and FIG. 3 is a plan view of the substrate processing apparatus of FIG. 1.

Referring to FIGS. 1 to 3, a substrate processing apparatus 10 according to an exemplary embodiment of the present invention includes an index module 100, a processing module 300, and an interface module 500.

According to the exemplary embodiment, the index module 100, the processing module 300, and the interface module 500 are sequentially arranged in a line. Hereinafter, a direction in which the index module 100 and the processing module 300 are disposed is referred to as a first direction 12, and when viewed from above, a direction vertical to the first direction 12 is referred to as a second direction 14, and a direction perpendicular to both the first direction 12 and the second direction 14 is referred to as a third direction 16.

The index module 100 transfers a substrate W from a container F in which the substrate W is accommodated to the processing module 300, and makes the substrate W, which has been completely processed, be accommodated in the container F. A longitudinal direction of the index module 100 is provided in the second direction 14. The index module 100 includes a load port 110 and an index frame 130. Based on the index frame 130, the load port 110 is located at a side opposite to the processing module 300. The containers F in which the substrates W are accommodated are placed on the load ports 110. The load ports 110 may be provided in plurality, and the plurality of load ports 110 may be disposed in the second direction 14.

As the container F, an airtight container, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided to the index frame 130. A guide rail 136 of which a longitudinal direction is the second direction 94 is provided within the index frame 14, and the index robot 132 may be provided to be movable on the guide rail 136. The index robot 132 includes a hand on which the substrate W is placed, and the hand may be provided to be movable forward and backward, rotatable about the third direction 16, and movable along the third direction 16.

The processing module 300 may perform an application process and a development process on the substrate W. The processing module 300 may perform a substrate processing process by receiving the substrate W accommodated in the container F. The processing module 300 includes an applying block 300a, a developing block 300b, and a front buffer chamber 310.

The applying block 300a performs an application process on the substrate W, and the developing block 300b performs a developing process on the substrate W. A plurality of applying blocks 300a is provided, and they are provided to be stacked on each other. A plurality of developing blocks 300b is provided, and they are provided to be stacked on each other. According to the exemplary embodiment of FIG. 1, two applying blocks 300a and two developing blocks 300b are provided, respectively. The applying blocks 300a may be disposed under the developing blocks 300b. According to an example, the two applying blocks 300a perform the same process and may be provided in the same structure. According to an example, the two developing blocks 300b perform the same process and may be provided in the same structure.

Referring to FIG. 3, the applying block 300a includes a heat processing chamber 320, a transfer chamber 350, and a liquid processing chamber 360.

The heat processing chamber 320 performs a heat processing process on the substrate W. The heat processing process may include a cooling process and a heating process. The liquid processing chamber 360 forms a liquid film by supplying a liquid onto the substrate W. The liquid film may be a photoresist film or an antireflection film. The transfer chamber 350 transfers the substrate W between the heat processing chamber 320 and the liquid processing chamber 360 within the applying block 300a.

The transfer chamber 350 may be provided so that a longitudinal direction is parallel to the first direction 12. A transfer robot 900 is provided to the transfer chamber 350. The transfer robot 900 transfers substrates between the heat processing chamber 320, the liquid processing chamber 360, and the buffer chambers 312 and 316. According to an example, the transfer robot 900 includes a hand on which the substrate W is placed, and the hand may be provided to be movable forward and backward, rotatable about the third direction 16, and movable along the third direction 16.

The front buffer chamber 310 may include a buffer transfer unit 2000, a plurality of buffer modules 312, and an adhesion baking module 315.

Some of the buffer modules 312 may include a cool plate where a substrate stands by before being introduced into the applying block 300a after adjustment baking processing.

An adhesion baking module 315 for hydrophobizing the surface of the substrate with hydrophobic gas before the applying process may be positioned at one side of the buffer transfer unit 2000. Herein, the hydrophobic gas may be hexamethyldisilane (HMDS).

The buffer transfer unit 2000 is disposed on one side of the buffer module 312. The buffer transfer unit 1000 may include a buffer loading robot 3312 that transfers a substrate before process processing to the applying module for the applying process, and a buffer unloading robot 3314 that transfers a substrate to a buffer module located at a third or fourth stage so that the index robot is capable of unloading the substrate after process processing.

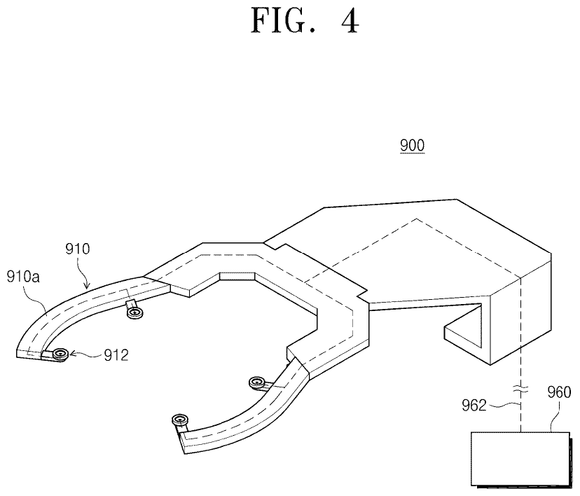

FIG. 4 is a diagram illustrating an example of the hand of the transfer robot.

Referring to FIG. 4, a hand 910 includes a hand main body 910a and supporting fingers 910b. The hand main body 910a is formed in an approximately horseshoe shape having an inner diameter greater than a diameter of the substrate. However, a shape of the hand main body 910a is not limited thereto. The supporting fingers 910b are installed in four positions including a front end portion of the hand main body 910a in an inward direction. The hand main body 910a has a vacuum flow path (not illustrated) therein. The vacuum flow path (not illustrated) is connected to a vacuum pump 960 through a vacuum line.

Referring back to FIGS. 1 to 3, a plurality of heat processing chambers 320 is provided. The heat processing chambers 320 are disposed along the first direction 12. The heat processing chambers 320 are located on one side of the transfer chamber 350.

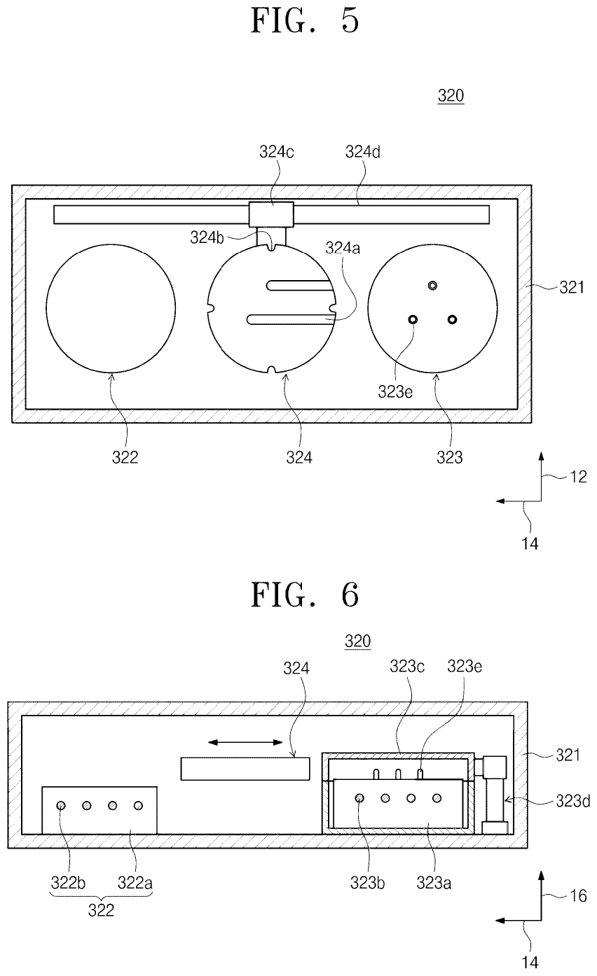

FIG. 5 is a plan view schematically illustrating one example of a heat processing chamber of FIG. 3, and FIG. 6 is a front view of the heat processing chamber of FIG. 5.

Referring to FIGS. 5 and 6, the heat processing chamber 320 includes a housing 321, a cooling unit 322, a heating unit 323, and a transfer plate 324.

The housing 321 is provided in a generally rectangular parallelepiped shape. An entrance opening (not illustrated) through which the substrate W enters and exits is formed on a sidewall of the housing 321. The entrance opening may remain open. A door (not illustrated) may be provided to selectively open and close the entrance opening. The cooling unit 322, the heating unit 323, and the transfer plate 324 are provided within the housing 321. The cooling unit 322 and the heating unit 323 are arranged along the second direction 14. According to an example, the cooling unit 322 may be positioned closer to the transfer chamber 350 than the heating unit 323.

The cooling unit 322 has a cooling plate 322a. When viewed from the top, the cooling plate 322a may have a substantially circular shape. A cooling member 322b is provided on the cooling plate 322a. According to an example, the cooling member 322b is formed inside the cooling plate 322a and may be provided as a flow path through which a cooling fluid flows.

The heating unit 323 includes a heating plate 323a, a cover 323c, and a heater 323b. When viewed from the top, the heating plate 323a has a generally circular shape. The heating plate 323a has a larger diameter than the substrate W. The heater 323b is installed on the heating plate 323a. The heater 323b may be provided as a heating resistor to which a current is applied. The heating plate 323a is provided with lift pins 323e that may be driven in the vertical direction along the third direction 16. The lift pin 323e receives the substrate W from the transfer means outside the heating unit 323, puts the received substrate W down on the heating plate 323a, or lifts the substrate W from the heating plate 323a to transfer the substrate W to the transfer means outside the heating unit 323. According to an example, three lift pins 323e may be provided. The cover 323c has a space in which a lower portion is open.

The cover 323c is positioned above the heating plate 323a and is moved in the vertical direction by a driver 3236d. A space formed by the cover 323c and the heating plate 323a by moving the cover 323c is provided as a heating space for heating the substrate W.

The transfer plate 324 is generally provided with a disk shape and has a diameter corresponding to that of the substrate W. A notch 324b is formed at an edge of the transfer plate 324. The notch 324b may have a shape corresponding to that of a protrusion 3543 formed in the hand 354 of the transfer robot 352 described above. Also, the notch 324b is provided by the number corresponding to that of the protrusions 3543 formed in the hand 354, and is formed at a position corresponding to that of the protrusion 3543. When the vertical positions of the hand 354 and the transfer plate 324 are changed at a position where the hand 354 and the transfer plate 324 are vertically aligned, the substrate W is transferred between the hand 354 and the transfer plate 324. The transfer plate 324 may be mounted on the guide rail 324d and may be moved between a first region 3212 and a second region 3214 along the guide rail 324d by a driver 324c. A plurality of slit-shaped guide grooves 324a is provided in the transfer plate 324. The guide groove 324a extends from the end of the transfer plate 324 to the inside of the transfer plate 324. The guide groove 324a is provided so that a longitudinal direction thereof is the second direction 14, and the guide grooves 324a are spaced apart from each other along the first direction 12. The guide groove 324a prevents the transfer plate 324 and the lift pin 323e from interfering with each other when the substrate W is taken over between the transfer plate 324 and the heating unit 323.

Cooling of the substrate W is performed in a state in which the transfer plate 324 on which the substrate W is placed is in contact with the cooling plate 322a. The transfer plate 324 is made of a material having high thermal conductivity so that heat transfer between the cooling plate 322a and the substrate W is well performed. According to an example, the transfer plate 324 may be made of a metal material.

Referring back to FIGS. 1 to 3, a plurality of liquid processing chambers 360 is provided. Some of the liquid processing chambers 360 may be provided to be stacked on each other. The liquid processing chambers 360 are disposed on one side of the transfer chamber 350. The liquid processing chambers 360 are arranged side by side along the first direction 12. Some of the liquid processing chambers 360 are provided at positions adjacent to the index module 100. Hereinafter, the liquid processing chamber 360 positioned adjacent to the index module 100 is referred to as a front liquid processing chamber 362. Another part of the liquid processing chambers 360 is provided at a position adjacent to the interface module 500. Hereinafter, the liquid processing chamber 360 positioned adjacent to the interlace module 500 is referred to as a rear liquid processing chamber 364.

The front liquid processing chamber 362 applies a first liquid on the substrate W, and the rear liquid processing chamber 364 applies a second liquid on the substrate W. The first liquid and the second liquid may be different types of liquids. According to an example, the first liquid is an antireflection film, and the second liquid is a photoresist. The photoresist may be applied on the substrate W to which the antireflection film is applied. Optionally, the first liquid may be a photoresist, and the second liquid may be an antireflection film. In this case, the antireflection film may be applied on the substrate W to which the photoresist is applied. Optionally, the first liquid and the second liquid are the same type of liquid, and all of them may be photoresist.

The developing block 300b has the same structure as the applying block 300a, and the liquid processing chamber provided to the developing block 300b supplies a developer on the substrate.

The interface module 500 connects the processing module 300 to an external exposure device 700. The interface module 500 includes an interface frame 510, an additional process chamber 520, an interface buffer 530, and an interface robot 550.

A fan filter unit that forms descending airflow therein may be provided at an upper end of the interface frame 510. The additional process chamber 520, the interface buffer 530, and the interface robot 550 are disposed within the interface frame 510. The additional process chamber 520 may perform a predetermined additional process before the substrate W on which the process has been completed in the applying block 300a is introduced into the exposure device 700. Selectively, the additional process chamber 520 may perform a predetermined additional process before the substrate W on which the process has been completed in the exposure device 700 is introduced into the developing block 300b. According to an example, the additional process may be an edge exposure process for exposing an edge region of the substrate W, an upper surface cleaning process for cleaning the upper surface of the substrate W, or a lower surface cleaning process for cleaning the lower surface of the substrate W. A plurality of additional process chambers 520 may be provided, and they may be provided to be stacked on each other. All of the additional process chambers 520 may be provided to perform the same process. Optionally, some of the additional process chambers 520 may be provided to perform different processes.

The interface buffer 530 provides a space in which the substrate W transferred between the applying block 300a, the additional process chamber 520, the exposure device 700, and the developing block 300b temporarily remains during transfer. A plurality of interface buffers 530 may be provided, and a plurality of interface buffers 530 may be provided to be stacked on each other.

According to an example, the additional process chamber 520 may be disposed on one side and the interface buffer 530 may be disposed on the other side based on an extension line of the transfer chamber 350 in the longitudinal direction.

The interface robot 550 transfers the substrate W between the applying block 300a, the additional process chamber 520, the exposure device 700, and the developing block 300b. The interface robot 550 may have a transfer hand to transfer the substrate W. The interface robot 550 may be provided as one or a plurality of robots. According to an example, the interface robot 550 has a first robot 552 and a second robot 554. The first robot 552 may be provided to transfer the substrate W between the applying block 300a, the additional process chamber 520, and the interface buffer 530, and the second robot 554 may be provided to transfer the substrate W between the interface buffer 530 and the exposure device 700, and the second robot 4604 may be provided to transfer the substrate W between the interface buffer 530 and the developing block 300b.

Each of the first robot 552 and the second robot 554 includes a transfer hand on which the substrate W is placed, and the hand may be provided to move forward and backward, rotate based on an axis parallel to the third direction 16, and move along the third direction 16.

Hereinafter, the structure of the liquid processing chamber will be described in detail. Hereinafter, the liquid processing chamber provided to the applying block will be described as an example. In addition, the preset invention will be described based on the case where the liquid processing chamber is a chamber which applies a photoresist on the substrate W. However, the liquid processing chamber may be a chamber forming a film, such as a protective film or an antireflection film, on the substrate W. Also, the liquid processing chamber may be a chamber for developing the substrate W by supplying a developer to the substrate W.

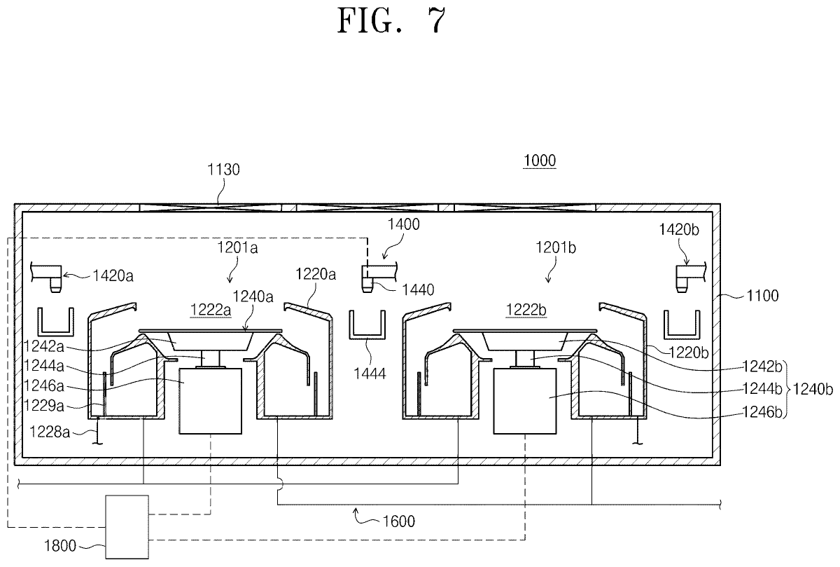

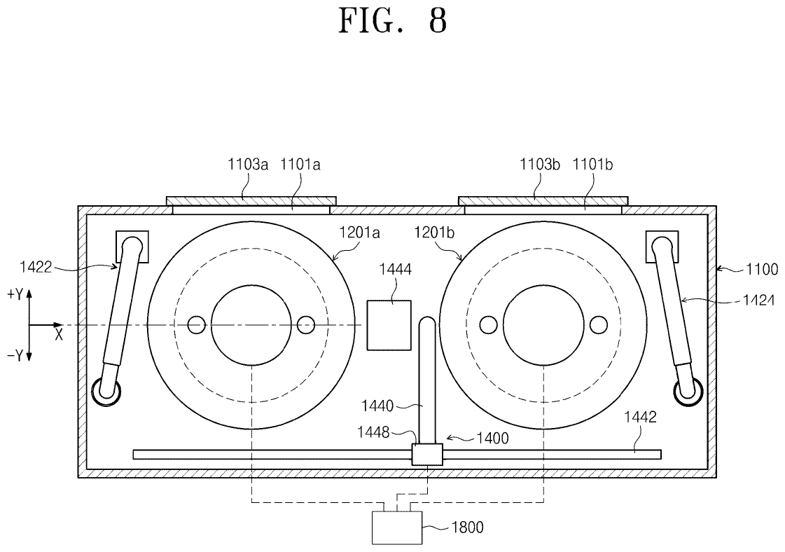

FIG. 7 is a cross-sectional view illustrating an exemplary embodiment of the liquid processing chamber for liquid-processing a substrate by supplying a processing liquid to a rotating substrate, and FIG. 8 is a plan view of the liquid processing chamber of FIG. 7.

Referring to FIGS. 7 and 8, the liquid processing chamber 1000 includes a housing 1100, a first processing unit 1201a, a second processing unit 1201b, a liquid supply unit 1400, an exhaust unit 1600, and a controller 1800.

The housing 1100 is provided in a rectangular cylindrical shape having an inner space. Openings 1101a and 1101b are formed at one side of the housing 1100. The openings 1101a and 1101b function as passages through which the substrate W is carried in and out. Doors 1103a and 1101b are installed in the openings 1101a and 1101b, and the doors 1103a and 1103b open and close the openings 1101a and 1101b.

A fan filter unit 1130 is disposed on the upper wall of the housing 1100 to supply downward airflow to the inner space. The fan filter unit 1130 has a fan for introducing external air into the inner space and a filter for filtering external air.

The first processing unit 1201a and the second processing unit 1201b are provided in the inner space of the housing 1100. The first processing unit 1201a and the second processing unit 1201b are arranged in one direction. Hereinafter, a direction in which the first processing unit 1201a and the second processing unit 1201b are arranged is referred to as a unit arrangement direction, and is illustrated in an X-axis direction in FIG. 11.

The first processing unit 1201a has a first processing container 1220a and a first supporting unit 1240a.

The first processing container 1220a has a first inner space 1222a. The first inner space 1222a is provided such that an upper portion thereof is opened.

The first supporting unit 1240a supports the substrate W in the first inner space 1222a of the first processing container 1220a. The first supporting unit 1240a has a first supporting plate 1242a, a first driving shaft 1244a, and a first driver 1246a. The first supporting plate 1242a has a circular upper surface. The first supporting plate 1242a has a smaller diameter than the substrate W. The first supporting plate 1242a is provided to support the substrate W by vacuum pressure. Selectively, the first supporting plate 1242a may have a mechanical clamping structure that supports the substrate W. The first driving shaft 1244a is coupled to a center of a bottom surface of the first supporting plate 1242a, and the first driving shaft 1244a is provided with the first driver 1246a that provides rotational force to the first driving shaft 1244a. The first driver 1246a may be a motor.

The second processing unit 1201b has a second processing container 1220b and a second supporting unit 1240b, and the second supporting unit 1240b has a second supporting plate 1242b, a second driving shaft 1244b, and a second driver 1246b. The second processing container 1220b and the second supporting unit 1240b have substantially the same structure as the first processing container 1220a and the first supporting unit 1240a.

The liquid supply unit 1400 supplies a liquid onto the substrate W. The liquid supply unit 1400 includes a first nozzle 1420a, a second nozzle 1420b, and a processing liquid nozzle 1440. The first nozzle 1420a supplies a liquid to the substrate W provided to the first support unit 1240a, and the second nozzle 1420b supplies a liquid to the substrate W provided to the second support unit 1240b. The first nozzle 1420a and the second nozzle 1420b may be provided to supply the same type of liquid. According to an example, the first nozzle 1420a and the second nozzle 1420b may supply a rinse liquid for cleaning the substrate W. For example, the rinse liquid may be water. According to another example, the first nozzle 1420a and the second nozzle 1420b may supply a removal liquid for removing a photoresist from an edge region of the substrate W. For example, the removal liquid may be a thinner. Each of the first nozzle 1420a and the second nozzle 1420b may be rotated between a process position and a standby position with respect to a rotation axis thereof. The process position is a position at which the liquid is discharged onto the substrate W, and the standby position is a position at which the first nozzle 1420a and the second nozzle 1420b wait without discharging the liquid onto the substrate W.

The processing liquid nozzle 1440 supplies the processing liquid to the substrate W provided to the first support unit 1240a and the substrate W provided to the second support unit 1240b. The processing liquid may be a photoresist. The nozzle driver 1448 drives the processing liquid nozzle 1440 so that the processing liquid nozzle 1440 moves between a first process position, a standby position, and a second process position along the guide 1442. The first process position is a position where the processing liquid is supplied to the substrate W supported by the first support unit 1240a, and the second process position is a position where the processing liquid is supplied to the substrate W supported by the second support unit 1240b. The standby position is a position where the processing liquid nozzle 1440 waits at the standby port 1444 located between the first processing unit 1201a and the second processing unit 1201b when the photoresist is not discharged from the processing liquid nozzle 1440.

A gas-liquid separating plate 1229a may be provided in the inner space 1201a of the first processing container 1220a. The gas-liquid separating plate 1229a may be provided to extend upward from a bottom wall of the first processing container 1220a. The gas-liquid separating plate 1229a may be provided in a ring shape.

According to an example, the outside of the gas-liquid separating plate 1229a may be provided as a discharge space for discharging liquid, and the inside of the gas-liquid separating plate 1229a may be provided as an exhaust space for exhausting the atmosphere. A discharge pipe 1228a for discharging a processing liquid is connected to the bottom wall of the first processing container 1220a. The discharge pipe 1228a discharges the processing liquid introduced between the sidewall of the first processing container 1220a and the gas-liquid separating plate 1229a to the outside of the first processing container 1220a. An airflow flowing into the space between the sidewall of the first processing container 1220a and the gas-liquid separating plate 1229a flows into the gas-liquid separating plate 1229a. In this process, the processing liquid contained in the airflow is discharged from the discharge space to the outside of the first processing container 1220a through the discharge pipe 1228a, and the airflow flows into the exhaust space of the first processing container 1220a.

Although not illustrated, an elevation driver for adjusting a relative height of the first supporting plate 1242a and the first processing container 1220a may be provided.

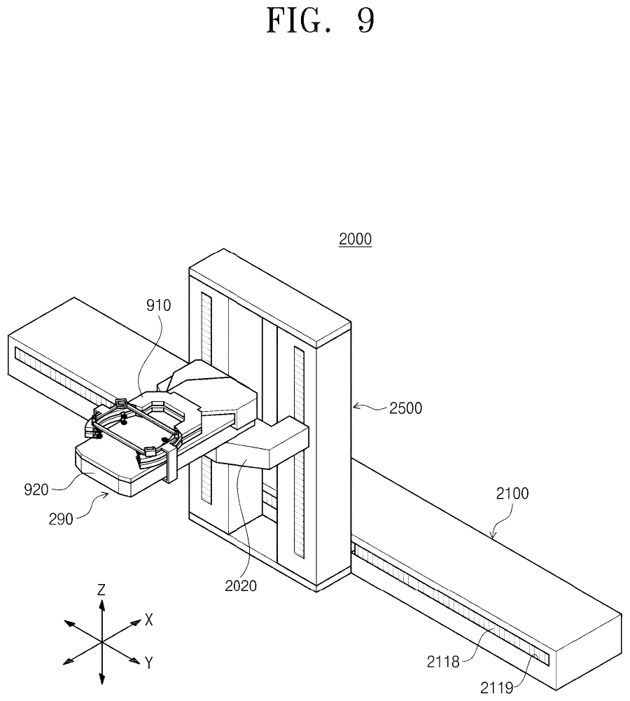

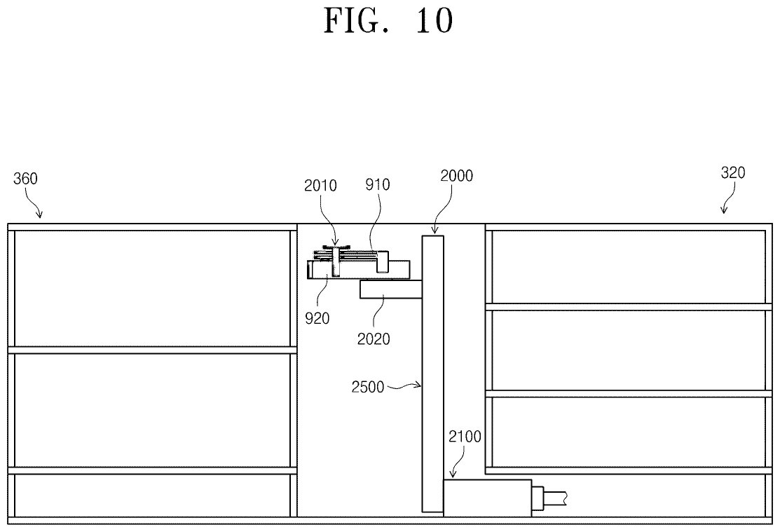

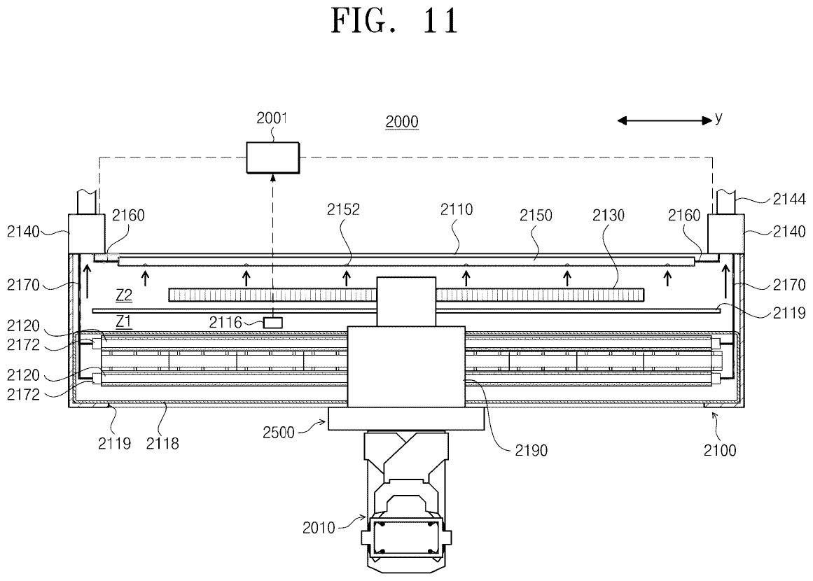

FIG. 9 is a perspective view illustrating an example of the transfer robot of FIG. 3, and FIG. 10 is a diagram illustrating the transfer chamber in which a transfer robot of FIG. 9 is installed.

Hereinafter, the present invention will be described based on the case where a transfer robot 2000 of FIG. 9 is the transfer robot of FIG. 3.

Referring to FIGS. 9 to 10, a transfer robot 2000 may include a robot main body 2010, a horizontal driving unit 2100, and a vertical driving unit 2500.

As described above, the horizontal driving unit 2100 is a driving guide for moving the robot main body 2010 in the Y direction (horizontal direction), and is coupled to the vertical driving unit 2500.

The vertical driving unit 2100 is a kind of driving unit for moving the robot main body 2010 in the Z direction, and is coupled to the horizontal driving unit 2500. Accordingly, the robot main body 2010 may be guided by the horizontal driving unit 2100 and moved in the Y direction while also being guided by the vertical driving unit 2500 and moved in the Z direction. That is, the robot main body 2010 may be moved in a diagonal direction corresponding to the sum of the Y direction and the Z direction. Meanwhile, the vertical driving unit 2500 includes a plurality of, for example, two, vertical frames spaced apart from each other, and the robot main body 2010 may be freely positioned in a space spaced between the two frames.

Each of the horizontal driving unit 2100 and the vertical driving unit 2500 is embedded with an actuator, which will be described in detail below.

The robot main body 2010 may include a hand 910 capable of supporting a substrate and moving forward and backward (X direction) and a hand driving unit 920 including a base supporting the hand 910.

The hand driving unit 920 horizontally moves the hand 910, and the hand 910 is individually driven by the hand driving unit 920. The hand driving unit 920 includes a connection arm connected to an internal driving unit (not illustrated), and the hand 910 is installed at an end of the connection arm. In the present exemplary embodiment, the transfer robot 2000 includes two hands 910, but the number of hands 910 may increase according to process efficiency of a substrate processing system 1000. The hand 910 includes an adsorption hole 912 for vacuum adsorption of a substrate. A vacuum line, which is a vacuum channel, is connected to the adsorption hole 912.

A hand base 2020 having a Z-axis rotation unit (not illustrated) may be provided below the hand driver 920. The hand base 2020 supports the hand driving unit 920 and rotates the hand driving unit 920 with respect to the Z-axis. Accordingly, the hands 910 rotate together. The hand base 2020 is connected to the vertical driving unit 2500.

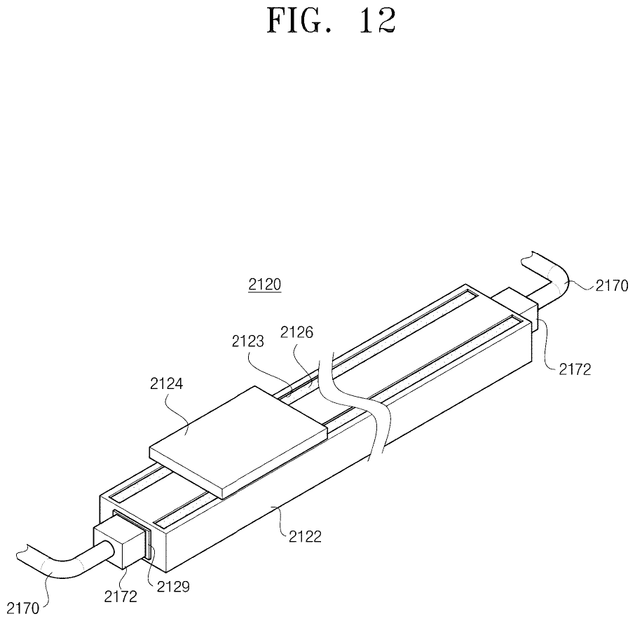

FIG. 11 is a plan view of the transfer robot, and FIG. 12 is a diagram for describing a horizontal driving unit.

Referring to FIG. 11, the horizontal driving unit 2100 may include a driving case 2110, a first actuator 2120, a first cable veyor 2130, an exhaust fan 2140, a first intake manifold 2150, a first intake line 2160 that provides a first intake path, and a second intake line 2170 that provides a second intake path.

The driving case 2110 has an inner space. The driving case 2110 is installed on a lower end of the transfer chamber. The exhaust fans 2140 may be installed on both sides of the rear surface of the driving case 2110, respectively. An opening 2116 is provided on the front surface of the driving case 2110. A slider 21190, which is connected to the vertical driving unit 2500, is located in the opening 2116, and the slider 2190 is provided to be movable in a horizontal direction along the opening 2116 by the first actuator 2120. A seal belt 2118 is provided inside the driving case to seal the opening 2116 and simultaneously to allow the slider 2190 to move. The seal belt 2118 is connected to the slider so as to move together with the slider 2190. A pressure measuring device 2116 that measures the internal pressure may be installed in the driving case 2110. The measured value of the pressure measuring device 2116 is provided to the controller. The controller may control the rotational speed of the exhaust fan according to the measured pressure.

FIG. 11 is a diagram for describing the actuator of the horizontal driving unit.

Referring to FIGS. 10 and 11, the actuator 2120 is provided in the driving case 2110 along the Y direction. For example, the actuator 2120 may be a linear motion guide having a shielding function. The linear motion guide 2120 may include a case 2122 having an opening 2123, a driving table 2124 mounted to be movable along the opening 2123 with respect to the case 2122, and a seal belt 2126 that closes the opening 2123 of the case 2122 and allows movement of the driving table 2124 at the same time. The driving table 2124 is connected to the slider 2190. An intake port 2129 is provided at both ends of the case 2122, and a second intake pipe 2170 which is a second intake path is connected to the intake port 2129.

The regulator 2172 is provided on the second intake pipe 2170 and adjusts suction force provided to the inside of the linear motion guide 2120 so that the inside of the linear motion guide 2120 maintains an appropriate pressure. Here, the appropriate pressure refers to a range in which the seal belt 2126 is capable of intaking particles in the case 2122 without being affected by the suction force of the exhaust fan 2140. For example, when the inside of the linear motion guide 2120 is out of an appropriate pressure due to excessive suction force of the exhaust fan 2140, the shape of the seal belt 2126 is deformed due to the excessive pressure, and thus the sealability of the opening 2123 is deteriorated. Therefore, the possibility that the particles flow out to the outside (in the driving case) through the opening 2123 of the case 2122 is increased. However, in the present invention, the internal pressure of the linear motion guide 2120 with a shielding function may be stably maintained by the regulator 2172, so that particles generated inside the case 2122 may be stably removed through the second intake pipe 2170 without leaking into the driving case 2110.

The cable veyor 2130 is installed in the driving case 2110 and guides the cable connected to the robot main body 2010. The cable veyor 2130 may be provided in a clean corrugated tube type instead of a chain type. The cable veyor 2130 may be installed in a separate space spaced apart from the linear motion guide 2120 by a predetermined distance. For example, the driving case 2110 may be divided into a first zone Z1 in which the linear motion guide 2120 is installed and a second zone Z2 in which the cable veyor 2130 is installed, and the first zone Z1 and the second zone Z2 may be partitioned by a partition plate 2119. The first zone Z1 and the second zone Z2 are not completely partitioned from each other, and may have a shape in which the upper end and opposite ends of the partition plate 2119 are open.

The first intake manifold 2150 intakes in the first zone Z1 where the cable veyor 2130 is located. The first intake pipe 2160 connected to the exhaust fan 2140 is connected to the first intake manifold 2150. The first intake manifold 2150 receives suction force from the exhaust fan 2140 through the first intake pipe 2160. The first intake manifold 2150 may be provided side by side in the longitudinal direction of the cable veyor 2130. Intake holes 2152 may be provided in one surface of the first intake manifold 2150 facing the cable veyor 2130.

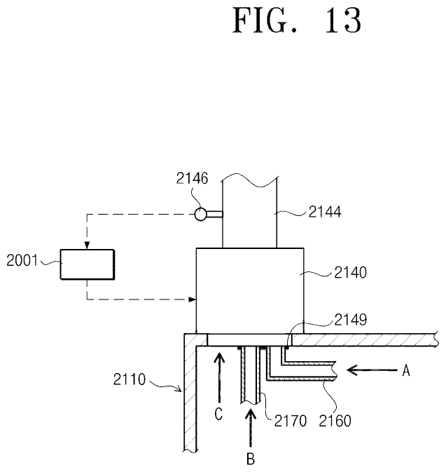

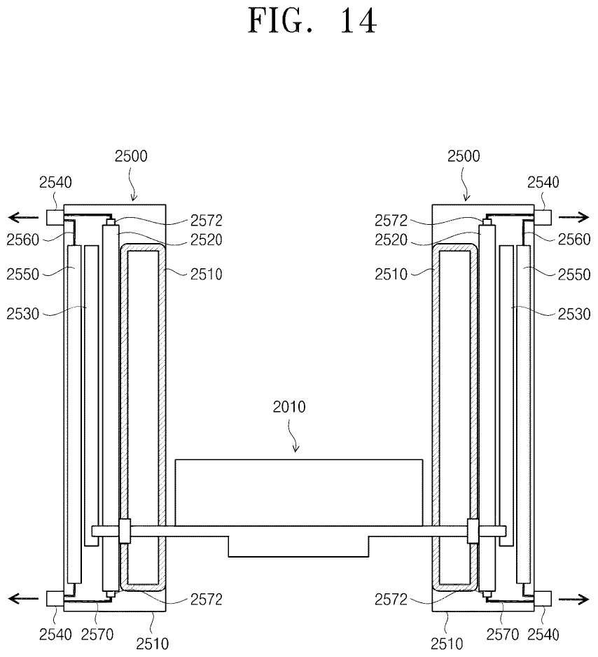

FIG. 13 is a diagram illustrating integrated exhaust of the exhaust fan.

Referring to FIGS. 11 to 13, the exhaust fan 2140 exhausts the atmosphere of the inner space of the driving case 2110. The first intake pipe 2160 and the second intake pipe 2170 are connected to the front surface of the exhaust fan 2140 by a flow path seal pad. Specifically, the exhaust fan 2140 may integrate and exhaust main exhaust airflow C inside the driving case 2110, first sub-exhaust airflow A of the first intake pipe 2160 connected to the first intake manifold 2150, and second sub-exhaust airflow B of the second intake pipe 2170 connected to the linear motion guide 2120.

An exhaust duct 2144 is connected to the exhaust fan 2140. The exhaust duct 2144 may be provided with a particle measuring device 2146 that detects particles from exhaust airflow. A measured value of the particle measuring device 2146 is provided to the controller 2001. The controller 2001 may increase the rotational speed of the exhaust fan 2140 when particles are measured to be greater than or equal to a reference value. As such, the controller 2001 may adjust the rotational speed of the exhaust fan 2140 according to the amount of particles included in the exhaust airflow.

As described above, the horizontal driving unit of the present invention may prevent particles from being exhausted by the first sub-exhaust airflow and the second sub-exhaust airflow and being scattered into the equipment process area when the particles occur in the linear motion guide 2120 and the cable veyor.

FIG. 14 is a diagram for describing the vertical driving unit in the transfer robot.

Referring to FIG. 14, the vertical driving unit 2500 includes a vertical driving case 2510, a second actuator 2520, a second cable veyor 2530, an exhaust fan 2540, a second intake manifold 2550, a third intake line 2560 that provides a third intake path, and a fourth intake line 2570 that provides a fourth intake path, which are provided with the substantially similar configurations and functions to the driving case 2110, the first actuator 2120, the first cable veyor 2130, the exhaust fan 2140, the first intake manifold 2150, the first intake line 2160 that provides the first intake path, and the second intake line 2170 that provides the second intake path, which are illustrated in FIG. 11, so the detailed descriptions thereof will be omitted.

The vertical driving unit 2500 may have an exhaust configuration substantially the same as that of the horizontal driving unit 2100 illustrated in FIG. 11.

The foregoing exemplary embodiments are presented for helping the understanding of the present invention, and do not limit the scope of the present invention, and it should be understood that various modified exemplary embodiments from the foregoing exemplary embodiments are also included in the scope of the present invention. The technical protection scope of the present invention should be determined by the technical spirit of the claims, and it should be understood that the technical protection scope of the present invention is not limited to the literal description of the claims itself, but is substantially equivalent to the technical value.

What is claimed is:

1. A substrate transfer apparatus disposed in a transfer chamber, the substrate transfer apparatus comprising:
a robot main body having hands supporting a substrate; and
a driving unit for moving the robot main body in a straight direction,
wherein the driving unit includes:
a driving case having an inner space;
an actuator provided within the driving case, and connected to the robot main body;
a cable veyor provided on one side of the actuator to guide the cable connected to the robot main body;
an exhaust fan for exhausting atmosphere of the inner space; and
an intake manifold for receiving suction force of the exhaust fan through a first intake path connected to the exhaust fan to intake a space where the cable veyor is located.

2. The substrate transfer apparatus of claim 1, further comprising:
a second intake path connected with the exhaust pan and the actuator to exhaust internal atmosphere of the actuator.

3. The substrate transfer apparatus of claim 2, wherein the actuator includes a linear motion guide having a shielding function, and
the linear motion guide includes:
a case having an opening;
a slider mounted to be movable along the opening with respect to the case; and
a seal plate for blocking the opening of the case and allowing the slider to move at the same time, and
the case includes an intake port connected to the second intake path.

4. The substrate transfer apparatus of claim 3, further comprising:
a regulator that is provided on the second intake path and regulates suction force provided to an inside of the actuator so that the inside of the actuator maintains a constant pressure.

5. The substrate transfer apparatus of claim 2, wherein the intake manifold is provided side by side along a longitudinal direction of the cable veyor and has intake holes on one side facing the cable veyor.

6. The substrate transfer apparatus of claim 2, further comprising:
a pressure measuring device for measuring an internal pressure of the driving case; and
a controller for controlling a rotational speed of the exhaust fan according to a measured value of the pressure measuring device.

7. The substrate transfer apparatus of claim 2, further comprising:
an exhaust duct through which airflow is exhausted through the exhaust fan;
a particle measuring device for detecting particles from airflow exhausted through the exhaust duct; and
a controller for controlling a rotational speed of the exhaust fan according to a measured value of the particle measuring device.

8. The substrate transfer apparatus of claim 2, wherein the exhaust fan integrates and exhausts main exhaust airflow inside the driving case, first sub exhaust airflow of the first intake path connected to the intake manifold, and second sub exhaust airflow of the second intake path connected to the actuator.

9. The substrate transfer apparatus of claim 2, wherein the actuator is horizontally installed inside the driving case to move the robot main body in a horizontal direction.

10. The substrate transfer apparatus of claim 2, wherein the actuator is vertically installed inside the driving case to move the robot main body in a vertical direction.

11. A substrate processing apparatus comprising:
a transfer chamber; and
a transfer apparatus disposed within the transfer chamber to transfer a substrate,
wherein the transfer apparatus includes:
a robot main body having hands supporting a substrate;
a vertical driving unit for moving the robot main body in a vertical direction; and
a horizontal driving unit provided at a bottom end of the transfer chamber to move the vertical driving unit in a horizontal direction, and
the horizontal driving unit includes:
a horizontal case having an inner space;
a first actuator provided horizontally within the horizontal case and connected to the vertical driving unit;
a first cable veyor that is provided on one side of the first actuator to guide the cable connected to the vertical driving unit;
a first exhaust fan for exhausting atmosphere of the inner space; and
a first intake manifold for receiving suction force of the first exhaust fan through a first intake path connected to the first exhaust fan to intake a space where the first cable veyor is located.

12. The substrate processing apparatus of claim 11, wherein the horizontal driving unit further includes a second intake path connecting the first exhaust fan and the first actuator to exhaust internal atmosphere of the first actuator.

13. The substrate processing apparatus of claim 12, wherein the first actuator includes a linear motion guide having a shielding function, and
the linear motion guide includes:
a case having an opening and an intake port connected to the second intake path;
a slider mounted to be movable along the opening with respect to the case; and
a seal plate capable of blocking the opening of the case and allowing the slider to move at the same time.

14. The substrate processing apparatus of claim 12, further comprising:
a regulator that is provided on the second intake path and regulates suction force provided to an inside of the first actuator so that the inside of the first actuator maintains a constant pressure.

15. The substrate processing apparatus of claim 12, wherein the intake manifold is provided side by side along a longitudinal direction of the first cable veyor and has intake holes on one side facing the first cable veyor.

16. The substrate processing apparatus of claim 12, further comprising:
a controller for controlling a rotational speed of the first exhaust fan,
wherein the controller controls the first exhaust fan according to a change in an internal pressure of the horizontal case or the amount of particles contained in the airflow exhausted through the first exhaust fan.

17. The substrate processing apparatus of claim 12, wherein the first exhaust fan integrates and exhausts main exhaust airflow inside the vertical case, first sub exhaust airflow of the first intake path connected to the intake manifold, and second sub exhaust airflow of the second intake path connected to the first actuator.

18. The substrate processing apparatus of claim 12, wherein the vertical driving unit includes:
a vertical case having an inner space;
a second actuator provided vertically within the vertical case and connected to the robot main body;
a second cable veyor that is provided on one side of the second actuator to guide a cable connected to the robot main body;
a second exhaust fan for exhausting atmosphere of the inner space; and
a second intake manifold for receiving suction force of the second exhaust fan through a third intake path connected to the second exhaust fan to intake a space where the second cable veyor is located;
a fourth intake path connecting the second exhaust fan and the second actuator to exhaust internal atmosphere of the second actuator; and
a regulator that is provided on the fourth intake path and regulates suction force provided to the inside of the second actuator so that the inside of the second actuator maintains a constant pressure.

19. A substrate transfer apparatus disposed in a transfer chamber, the substrate transfer apparatus comprising:
a robot main body having hands supporting a substrate; and
a driving unit for moving the robot main body in a straight direction,
wherein the driving unit includes:
a driving case having an inner space;
a linear motion guide provided in the driving case, connected to the robot body, and having a shielding function;
a cable veyor provided on one side of the linear motion guide to guide a cable connected to the robot main body;
an exhaust fan for exhausting atmosphere of the inner space; and
an intake manifold for receiving suction force of the exhaust fan through a first intake path connected to the exhaust fan to intake a space where the cable veyor is located;
a second intake path connecting the exhaust fan to the linear motion guide to exhaust internal atmosphere of the linear motion guide; and
a regulator that is provided on the second intake path and regulates suction force provided to an inside of the linear motion guide so that the inside of the linear motion guide maintains a certain pressure, and
the linear motion guide includes:
a case having an opening and an intake port connected to the second intake path;
a slider mounted to be movable along the opening with respect to the case; and
a seal plate for blocking the opening of the case and allowing the slider to move at the same time, and
the intake manifold is provided side by side along a longitudinal direction of the cable veyor and has intake holes on one side facing the cable veyor, and
the exhaust fan integrates and exhausts main exhaust airflow inside the driving case, first sub exhaust airflow of the first intake path connected to the intake manifold, and second sub exhaust airflow of the second intake path connected to the linear motion guide.

20. The substrate transfer apparatus of claim 19, further comprising:
a controller for controlling a rotational speed of the exhaust fan,
wherein the controller controls the exhaust fan according to a change in an internal pressure of the driving case or the amount of particles contained in the airflow exhausted through the exhaust fan.
